(19) United States
(12) Patent Application Publication
(10) Pub. No.: US 2013/0076416 A1
(43) Pub. Date: Mar. 28, 2013

(54) SUB-MICRON CMOS VCO THAT USES DELAY-BASED CALIBRATION AND METHOD OF OPERATION

(71) Applicant: Vamsi Mocherla, Hyderabad (IN)

(72) Inventor: Vamsi Mocherla, Hyderabad (IN)

(73) Assignee: Conexant Systems, Inc., Newport Beach, CA (US)

(21) Appl. No.: 13/242,078

(22) Filed: Sep. 23, 2011

(51) Int. Cl. H03L 7/00

(52) U.S. Cl. 327/160

(57) ABSTRACT

A system for calibrating a circuit comprising a delay to voltage converter for receiving an input signal and generating an output signal that represents a delay metric. A counter for receiving the output signal and generating a binary output as a function of the delay metric.

### TECHNICAL FIELD

The present disclosure generally relates to voltage-controlled oscillators (VCOs), and more specifically to delay-based calibration for a sub-micron CMOS VCO.

### BACKGROUND OF THE INVENTION

VCOs are known in the art. While VCOs have many useful applications, uncalibrated VCOs suffer from a number of shortcomings, such as phase noise and process-voltage-temperature (PVT) variations.

### SUMMARY OF THE INVENTION

A system for calibrating a circuit is provided. The system includes a delay to voltage converter for receiving an input signal and generating an output signal that represents a delay metric, such as a variation in ring-type oscillator inverter cell operation as a function of PVT variations. A counter receives the output signal and generates a binary output as a function of the delay metric, such as a binary signal that can be used to control the state of a plurality of switches that are used to calibrate the inverter cell.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims.

### BRIEF DESCRIPTION OF THE SEVERAL VIEWS OF THE DRAWINGS

Aspects of the disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views, and in which:

FIG. 1 is a diagram of a circuit for calibrating a VCO in accordance with an exemplary embodiment of the present disclosure;

FIG. 2 is a diagram of a system for calibrating a circuit in accordance with an exemplary embodiment of the present disclosure;

FIG. 3 is a diagram of a timing sequence for a calibration circuit in accordance with an exemplary embodiment of the present disclosure;

FIG. 4 is a diagram of an algorithm for controlling a circuit calibration process in accordance with an exemplary embodiment of the present disclosure; and

FIG. 5 is a diagram of a capacitor bank in accordance with an exemplary embodiment of the present disclosure.

### DETAILED DESCRIPTION OF THE INVENTION

In the description that follows, like parts are marked throughout the specification and drawings with the same reference numerals. The drawing figures might not be to scale and certain components can be shown in generalized or schematic form and identified by commercial designations in the interest of clarity and conciseness.

In sub-micron processes, core transistor based VCOs with 1 volt V_{DD} are non-linear. Because the threshold voltages are not scaled and have a limited common mode voltage range, the existing VCO architectures give a limited frequency range in one process-voltage-temperature (PVT) corner (slow, high temperature), while the opposite PVT corner (fast, high/low temperature) gives a high frequency range with respect to the control voltage. This high frequency range is normally unused and results in more than two times the VCO gains compared to the typical/slower corners.

The present disclosure relates to a system and method for tracking delay over the PVT corners for each VCO delay cell. Two delay cells with similar type load capacitors are used and the delay is captured and provided to a comparator, which freezes a counter. The code at the output of the counter is used to calibrate the delay of each delay cell, giving equal delays over PVT variations and hence the same frequency range.

An integrated CMOS VCO is an important block in a phase locked loop (PLL) frequency synthesizer design. The ring oscillator-based VCO incorporate an odd number of inverter stages to satisfy the Barkhausen criterion. The gain of the VCO (K_{VCO}) and the individual phase noise mask at a frequency offset contributes to the overall jitter and the integrated phase noise of the PLL. The gain of the VCO has a dependence on the input common mode range of the control voltage and the frequency range of operation as per the equation:

K_{VCO}=∂f_{VCO}/∂V_{CTRL}

In sub-micron processes, the transistors for the core power supplies are scaled for very high conductivity and hence high trans-conductance, in order to compensate for the loss of operating range due to non-scaling of the threshold voltage V_{TH}. These transistor variations of the CMOS VCO make it more difficult to achieve a low phase noise and constant frequency range over the PVT corners. In fast process corners, the range of the VCO is shifted to a higher frequency range but the phase noise worsens. In slow process corners, the VCO range becomes poorer but the phase noise is reasonably better.

The disclosed calibration circuit for the VCO of the present disclosure works in real time, and has a low footprint and power consumption. The design is portable over various processes. The design incorporates a simple CMOS VCO with a capacitive load bank, scaled up in a binary fashion. The current source for the VCO is also programmed with respect to the PVT or ambient variations. Binary scaling of the current provided to the VCO can be used to incorporate a very good correction and linearity for the slower and colder corners. The VCO delay cell can be a simple digital inverter type, though a differential delay cell can also be implemented, to have the maximum phase noise/area ratio. With the tuning of the V_{CTRL}, voltage, the current in the VCO is also tuned and frequency of the VCO is also changed. In this implementation, as V_{CTRL} increases, the frequency of the VCO is reduced in order to account for the slow, 125° C. corners to have supply side margin.

The calibration circuit of the VCO can include a delay block with scaled/similar values of the delay cells and a unit capacitor load to operate at the similar operating conditions as the VCO delay cells. A logical delay due to a reference frequency input is captured on a capacitor in a delay to voltage converter circuit, and the output of the delay to voltage converter circuit is provided to a comparator, whose output freezes a binary counter. When the voltage on the comparator output exceeds a reference voltage, such as V_{DD}/2 to account for voltage variations, the counter freezes and the counting code is passed on to registers. After a calibration end code is received at the register, the code is passed on the VCO where binary capacitor banks and current transistors are programmed to provide settings for the VCO operation. The calibration circuit is dynamic and can dynamically change the calibration code as per a setting on a calibration enable signal.

Every time calibration is needed, a calibration enable signal can be cycled from LOW to HIGH and a new code can be generated. Calibration overrun protection can also be used to freeze the calibration code to a maximum value, in order to protect the registers from overrunning the code value and starting over from 0. The counter can operate on ⅙th of the reference frequency or other suitable frequencies, such as based on a resolution factor of the calibration block. The frequency of operation also can be changed for better resolution of the calibration code. The calibration circuit can also incorporate override protection so that a designer/tester can operate with preset values of the code.

The disclosed calibration procedure can take several microseconds as per the code map, and can be described by the equation:

T_{CALIB}=(T_{REF}*2^{NCODE})/N_{FACTOR}

### WHERE

T_{REF}=1/F_{REF}, where F_{REF} is the reference frequency of operation from the crystal

N_{CODE}=the counter bit width, and

N_{FACTOR}=the resolution factor of the calibration block

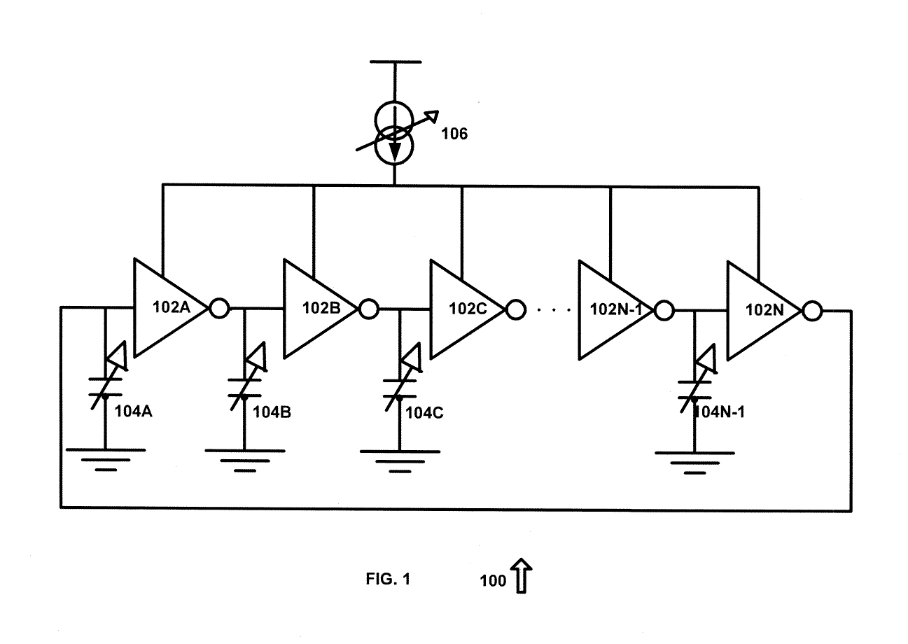

FIG. 1 is a diagram of a circuit 100 for calibrating a VCO in accordance with an exemplary embodiment of the present disclosure. Circuit 100 uses an adjustable capacitor bank to calibrate a VCO over PVT variations.

Circuit 100 can be implemented in silicon, gallium arsenide, or other suitable materials, and can be implemented as an integrated circuit, as discrete devices or in other suitable manners. Circuit 100 includes inverters 102A through 102N, which are coupled to one or more of controllable capacitor banks 104A through 104N−1. Variable voltage source 106 allows the voltage level applied (and the corresponding current provided) to inverters 102A through 102N and controllable capacitor banks 104A through 104N−1 to be varied to control a frequency of oscillation or other suitable circuit parameters.

In operation, circuit 100 receives a control signal that is used to set controllable capacitor banks 104A through 104N−1, so as to calibrate the frequency response as a function of applied voltage of circuit 100. Inverters 102A through 102N form a ring type oscillator and have an oscillation frequency that is a function of the delay of each inverter stage and the applied voltage. Due to PVT variations, the oscillation frequency can vary significantly if controllable capacitor banks 104A through 104N−1 and variable voltage source 106 are not used. Circuit 100 allows the voltage level and capacitance to be varied during a calibration procedure so as to allow the oscillation frequency of circuit 100 to be calibrated.

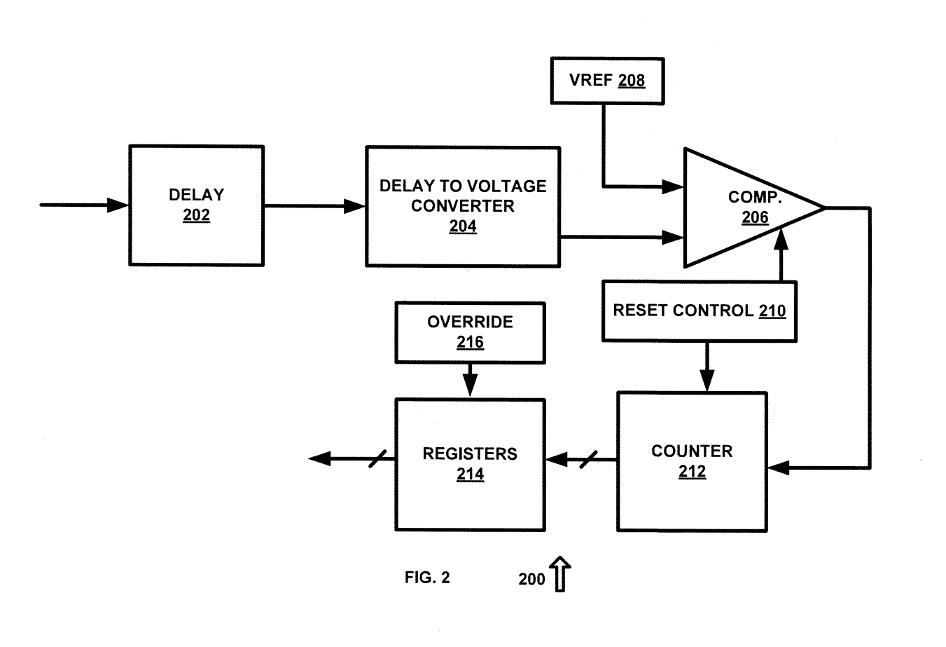

FIG. 2 is a diagram of a system 200 for calibrating a circuit in accordance with an exemplary embodiment of the present disclosure. System 200 can be implemented in hardware or a suitable combination of hardware and software, and can be one or more integrated circuits.

As used herein, “hardware” can include a combination of discrete components, an integrated circuit, an application-specific integrated circuit, a field programmable gate array, or other suitable hardware. As used herein, “software” can include one or more objects, agents, threads, lines of code, subroutines, separate software applications, two or more lines of code or other suitable software structures operating in two or more software applications or on two or more processors, or other suitable software structures. In one exemplary embodiment, software can include one or more lines of code or other suitable software structures operating in a general purpose software application, such as an operating system, and one or more lines of code or other suitable software structures operating in a specific purpose software application.

System 200 includes delay 202, which receives a reference clock signal and generates a delay pulse having a pulse width proportional to PVT variations of the devices used to fabricate delay 202. In one exemplary embodiment, delay 202 can be two inverter circuits having a design and configuration similar to that of inverter circuits that are used in the circuit to be calibrated.

Delay to voltage converter 204 receives the delay pulse from delay 202 and generates a voltage ramp signal as a function of the delay pulse, such as by applying the delay pulse to a capacitance. In one exemplary embodiment, the parameters of the voltage ramp signal, such as the rise time, can be a function of the PVT variations of the components of delay 202, such that the PVT variations of delay 202 (and the corresponding circuit being calibrated) can be determined based on the rise time.

Comparator 206 receives a reference voltage signal from voltage reference 208 and the output of delay to voltage converter 204 and generates a counter freeze signal. In one exemplary embodiment, the counter freeze signal can be generated when the magnitude of the output of delay to voltage converter 204 is equal to one half of V_{DD}.

Reset control 210 is used to reset comparator 206 and counter 212, such as to prevent counter 212 from overrunning its maximum value. If counter 212 is allowed to overrun its maximum value (such as if counter 212 were to begin counting from a value other than 0), then the output of counter 212 would not be calibrated to the expected value for the corresponding elapsed time.

Counter 212 begins counting upon receipt of the signal from reset control 210 and stops counting upon receipt of the counter freeze signal from comparator 206. In one exemplary embodiment, counter 212 can be a four bit counter that has counter overrun protection, such that counter 212 generates values ranging from [0 0 0 0] to [1 1 1 1] and does not loop back to [0 0 0 0].

Registers 214 receive the output of counter 212 and store the corresponding control values for calibrating the circuit. In one exemplary embodiment, registers 214 can correspond to switches for one or more switched capacitor banks, such that the bit value in each register is used to control one switch setting in each bank (e.g. “0” is closed and “1” is open).

Override 216 allows a user, a control system or other sources to provide register values for register 214, such as to allow the user to perform additional testing of the circuit that is being calibrated.

In operation, system 200 allows a circuit such as a VCO to be calibrated, by using a delay 202 or other suitable circuits to generate a pulse or other suitable calibration signals. The value of the calibration signal is used to generate a control code, such as a binary code that controls a plurality of switch states. Counter overrun, reset controls and override controls can be used to prevent misoperation of system 200.

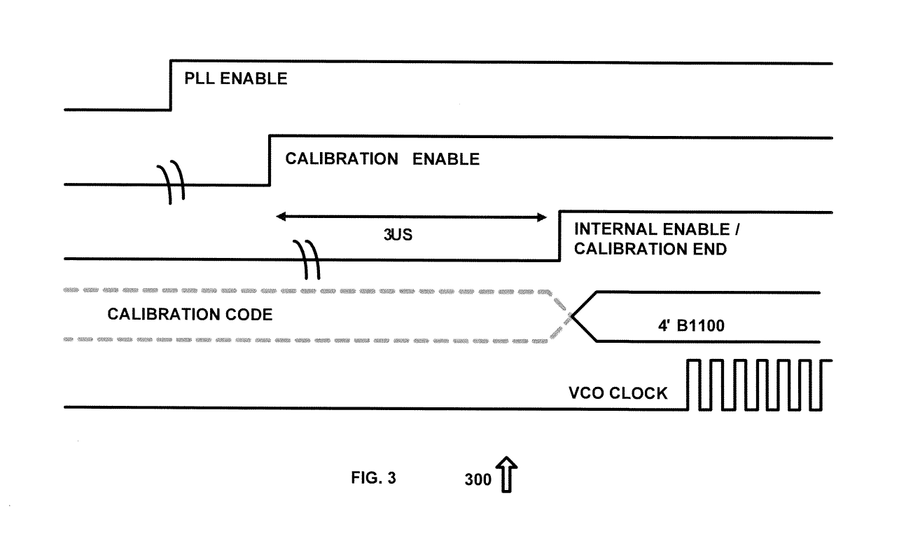

FIG. 3 is a diagram 300 of an exemplary timing sequence for a calibration circuit in accordance with an exemplary embodiment of the present disclosure. Diagram shows a PLL enable signal that initiates first, which is followed by a calibration enable signal. Over a period of time, such as three microseconds, the calibration process takes place, and a calibration code is then generated. Following generation of the calibration code and setting of the capacitor bank values and supply voltage values, the calibrated VCO clock signal is generated.

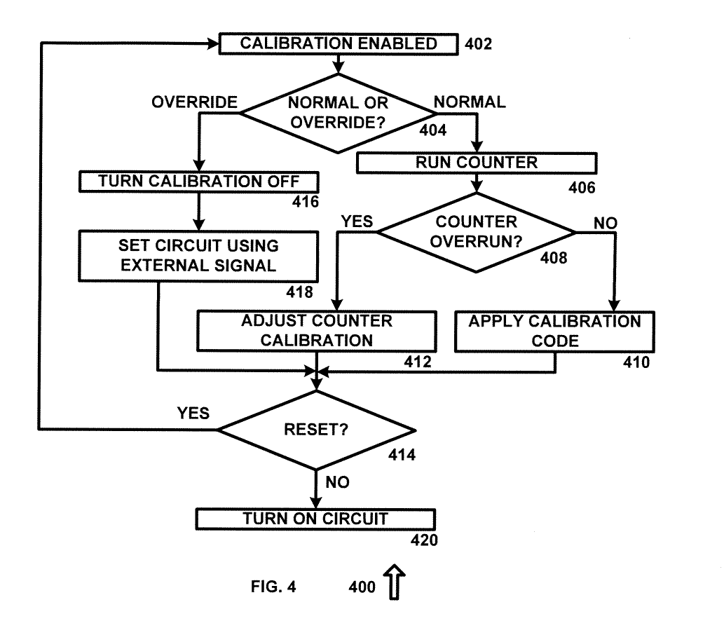

FIG. 4 is a diagram of an algorithm 400 for controlling a circuit calibration process in accordance with an exemplary embodiment of the present disclosure. Algorithm 400 begins at 402, where a calibration enable signal is generated. In one exemplary embodiment, the calibration enable signal can be generated by a control circuit that is used to control the operation of a VCO and other circuits and systems. The algorithm then proceeds to 404.

At 404, it is determined whether a normal or override mode of operation is in effect, such as by determining whether an override mode signal is present or in other suitable manners. If it is determined that operation is in override mode, the algorithm proceeds to 416, otherwise the algorithm proceeds to 406.

At 406, a counter is started and a reference clock signal is applied to a delay block or other suitable calibration circuits. The algorithm then proceeds to 408, where it is determined whether counter overrun has occurred. In one exemplary embodiment, counter overrun can result in the generation of an overrun signal that indicates that the counter timed out prior to receipt of a counter freeze signal from a comparator or other suitable components. If counter overrun has occurred, the algorithm proceeds to 412 where the calibration of the counter is adjusted, such as by resetting the counter to zero. The algorithm then proceeds to 414.

If it is determined at 408 that counter overrun has not occurred, the algorithm proceeds to 410 where the calibration code is applied to the circuit, such as by using binary calibration code values to control the state of a plurality of switches or in other suitable manners. The algorithm then proceeds to 414.

If it is determined at 404 that override mode is in operation, the algorithm proceeds to 416 where calibration is turned off. The algorithm then proceeds to 418 where the circuit settings are generated using an external signal. In one exemplary embodiment, a system controller, a user or other suitable sources can cause switch settings or other suitable circuit settings to be provided to the circuit that would otherwise be calibrated. The algorithm then proceeds to 414.

At 414, it is determined whether a reset signal has been received. If a reset signal has been received, the algorithm returns to 402, otherwise the algorithm proceeds to 420 where the calibrated or otherwise controlled circuit is turned on.

In operation, algorithm 400 allows a circuit to be automatically calibrated, such as by converting a PVT indicator into a delay metric and adjusting capacitor bank settings based on the delay. Algorithm 400 thus facilitates automatic calibration, overrun settings, override settings and other suitable features of an automatic calibration circuit.

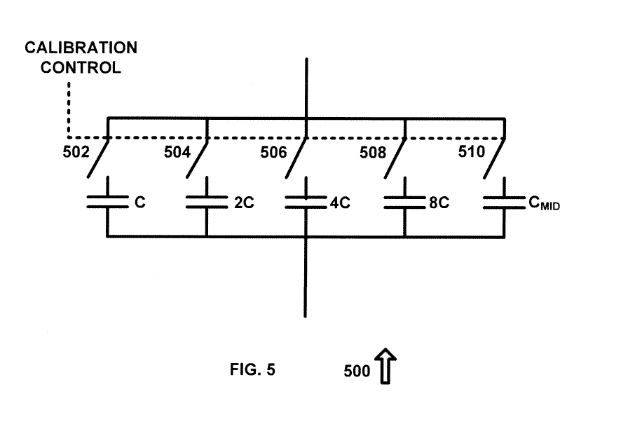

FIG. 5 is a diagram of a capacitor bank 500 in accordance with an exemplary embodiment of the present disclosure. Capacitor bank 500 includes switches 502 through 510, each of which is coupled to one of capacitors C through C_{MID}. Switches 502 through 510 can receive a binary code, such as [0 0 0 0 0] to close all switches, [1 1 1 1 1] to open all switches, and other suitable variations. In one exemplary embodiment, capacitor C_{MID} can be unswitched. A calibration control signal is provided to each of the switches 502 through 510, such as a separate control signal for each switch.

In one exemplary embodiment, the capacitor values can be provided as follows:

| S. No | Cap Name | Cap Area | Cap Values |
|---|---|---|---|
| 1. | Cmid | 4 × 4 | 90 fF |
| 2. | C1 | 4 × 4 | 90 fF |
| 3. | C2 | 2 × 4 × 4 | 180 fF |
| 4. | C3 | 4 × 4 × 4 | 360 fF |
| 5. | C4 | 8 × 4 × 4 | 720 fF |

where calibration is performed using capacitors of 10×10=560 fF.

It should be emphasized that the above-described embodiments are merely examples of possible implementations. Many variations and modifications may be made to the above-described embodiments without departing from the principles of the present disclosure. All such modifications and variations are intended to be included herein within the scope of this disclosure and protected by the following claims.

What is claimed is:

1. A system for calibrating a circuit comprising:
a delay to voltage converter for receiving an input signal and generating an output signal that represents a delay metric; and
a counter for receiving the output signal and generating a binary output as a function of the delay metric.

2. The system of claim 1 further comprising a delay for generating the input signal, wherein the input signal comprises a pulse having a width proportional to the delay metric.

3. The system of claim 1 wherein the delay metric is a function of PVT variations.

4. The system of claim 1 further comprising:
a voltage reference; and
a comparator for receiving the voltage reference and the output signal from the delay to voltage converter, wherein the comparator is for generating the output signal for the counter when a magnitude of the output signal from the delay to voltage converter exceeds a magnitude of the reference voltage.

5. The system of claim 1 further comprising a plurality of switches, and each of the switches is coupled to a capacitor.

6. The system of claim 1 further comprising a plurality of switches, and each of the switches is coupled to a capacitor, wherein each digit of the binary output controls a state of one of the switches.

7. The system of claim 1, further comprising a plurality of capacitor banks, wherein each capacitor bank comprises a plurality of switches, and each of the switches is coupled to a capacitor.

8. The system of claim 7, further comprising a plurality of inverters, and each of the inverters is coupled to one or more of the capacitor banks.

9. The system of claim 1, further comprising a voltage source controller coupled to the counter and receiving the binary output, wherein the binary output controls a voltage level applied to a plurality of inverters by the voltage source controller.

10. A method for calibrating a circuit comprising:
applying a reference signal to a delay;
providing an output from the delay to a delay to voltage converter, wherein the output of the delay varies as a function of a circuit parameter of the delay; and
generating a binary output as a function of an output of the delay to voltage converter.

11. The method of claim 10 wherein generating the binary output as the function of the output of the delay to voltage converter comprises:
comparing the output of the delay to voltage converter to a reference voltage; and
terminating a counter when the output of the delay to voltage converter exceeds the reference voltage.

12. The method of claim 11 wherein the counter generates the binary output.

13. The method of claim 10 further comprising controlling a plurality of switches with the binary output.

14. The method of claim 10 further comprising controlling a state of each of a plurality of switches with the binary output, wherein each digit of the binary output controls the state of one of the switches.

15. The method of claim 10 further comprising controlling a plurality of switches with the binary output, wherein each of the switches is coupled to a capacitor.

16. The method of claim 10 further comprising controlling a plurality of capacitor banks with the binary output, wherein each of the capacitor banks is coupled to one or more inverter.

17. The method of claim 10 further comprising controlling a plurality of capacitor banks with the binary output, wherein each digit of the binary output controls the state of one of a plurality of switches in each of the capacitor banks.

18. The method of claim 17 further comprising controlling a voltage level controller with the binary output, wherein the voltage level controller controls two or more voltage levels applied to a plurality of inverters as a function of the binary output.

19. A system for calibrating a circuit comprising:
means for receiving an input signal and generating an output signal that represents a delay metric; and
means for receiving the output signal and generating a binary output as a function of the delay metric.
